(19) United States
(12) Patent Application Publication
(10) Pub. No.: US 2023/0207661 A1
(43) Pub. Date: Jun. 29, 2023

(54) Semiconductor Device and Method of Manufacturing the Same

(71) Applicant: Nippon Telegraph and Telephone Corporation, Tokyo (JP)

(72) Inventors: Takuya Hoshi, Tokyo (JP); Yuki Yoshiya, Tokyo (JP); Yuta Shiratori, Tokyo (JP); Hiroki Sugiyama, Tokyo (JP)

(21) Appl. No.: 17/920,479

(22) PCT Filed: Apr. 23, 2020
(86) PCT No.: PCT/JP2020/017453

§ 371 Date: Mar. 1, 2023

(51) Int. Cl. H01L 29/66; H01L 29/20; H01L 29/778

(52) U.S. Cl. CPC H01L 29/66462; H01L 29/2003; H01L 29/7786

(57) ABSTRACT

An oxide layer (109) including an oxide of an electrode (108) material is formed by heating in a portion of an electrode (108) in contact with a surface oxidized layer (107). The oxide layer (109) is placed between the electrode (108) and an i-AlGaN layer (106) in contact with both the i-AlGaN layer (106) and the electrode (108).

### TECHNICAL FIELD

The present disclosure relates to a semiconductor device including a nitride semiconductor and a method for manufacturing the semiconductor device.

### BACKGROUND ART

Gallium nitride (GaN)-based materials have a large bandgap and high dielectric breakdown electric field strength, and thus are promising as materials of high withstand voltage power devices and high-power, high-frequency devices. GaN has a hexagonal wurtzite structure as a stable phase and generates polarization in the c-axis direction. By utilizing this effect, highly concentrated two-dimensional electron gas can be formed at an interface between AlGaN and GaN. High electron mobility transistors (HEMTS) which utilize two-dimensional electron gas have been actively studied.

In addition, heterojunction bipolar transistors (HBTS) which are vertical devices including nitride semiconductors are expected to be used in high-frequency and power applications due to their ability to increase current density and power density compared to HEMTS. In addition to transistors, many high-performance devices have been reported for two-terminal devices such as Schottky barrier diodes and p-n junction diodes.

In the application of GaN HEMTS as power devices, from the viewpoint of compensating for the operation of electronic circuits, so-called normally-off operation is desired in which a transistor is turned off when de-energized. In recent years, a gate injection transistor (GIT) structure has been actively researched and developed as one of the technologies for normally-off operation of GaN HEMTS. In the GIT structure, a p-GaN layer is formed on the AlGaN barrier layer in the gate region to lift the conduction band energy to achieve normally-off operation. Compared to the normally-off technique in the prior art, the GIT structure can be formed without including the recess etching process of the AlGaN barrier layer, and thus the GIT structure has superior controllability and productivity, as well as the ability to fabricate devices using only GaN-based materials, and makes it possible to create high-performance devices using GaN substrates or the like.

A p-type layer is also very useful in a GaN MOSFET structure. For example, in a vertical MOSFET structure, by forming a p-n junction with a p-type region immediately below a channel region, and the vertical MOSFET structure may be used for so-called current narrowing to concentrate a current in the region immediately below a gate. It is also possible to use the p-n junction for element separation.

HBTS typically have an n-p-n structure in order to use electrons with high electron velocity as carriers to increase an operating speed. Therefore, a GaN-based material doped with p-type impurities at high concentration is used for the base layer. However, doping the GaN-based material with p-type impurities at high concentration to increase a hole concentration in the GaN-based material (high hole concentration) is technically very difficult.

As described above, the importance of controlling the p-type layer is increasing to improve the performance of GaN devices. At the same time, the technique of forming an ohmic contact with electrodes is very important not only for real devices but also, for example, in a process of evaluating the crystal quality of the p-type GaN layer. However, the technique to form low-resistance ohmic electrodes for p-type GaN has not yet been achieved.

Ni-based electrodes have already been reported as a technique to form ohmic electrodes for p-type GaN (NPLs 3 to 5). it is normally said that in Ni electrodes, NiO formed by oxidation by annealing in an atmosphere such as air reduce contact resistance. However, as described above, it is not easy to increase the hole concentration of the p-type GaN, so if Ni is simply deposited and subjected to air annealing, a sufficiently low contact resistance cannot be obtained.

One of the techniques to increase the hole concentration in a GaN-based material is to use a two-dimensional hole gas. By forming the interface between AlGaN and GaN with a polarization axis reversed from that of HEMTs in the prior art, a bending of the valence band toward the Fermi level can be formed at the interface between AlGaN and GaN to generate a two-dimensional hole gas. This structure in which the polarization effect in nitride semiconductors is utilized to obtain a high hole concentration is applicable to a variety of devices (NPL 1).

However, the structure in which the interface between AlGaN and GaN with the polarization axis reversed as described above has difficulties in ohmic electrode formation. In this structure, two-dimensional hole gas is generated immediately below an AlGaN layer, which is generated at the hetero-interface due to the effect of polarization of AlGaN and GaN. However, since AlGaN is a high-resistance material, forming electrodes through AlGaN can be an obstacle to low contact resistance. On the other hand, when a recess is etched into the AlGaN layer to form a direct contact in GaN, the two-dimensional hole gas is eliminated immediately below the recess-etched AlGaN layer, and the effect of the two-dimensional hole gas cannot be fully utilized (NPL 2).

### CITATION LIST

### Non Patent Literature

NPL 1: Yuto Ando et al., “Fabrication of Collector-top Vertical Gallium Nitride Heterojunction Bipolar Transistor with 2DHG”, Proceedings of the 64th JSAP Spring Meeting, 15a-315-7, 12-129, 2017.
NPL 2: Kumabe, Takeru, et al., “Emitter-top GaN HBT with Two-dimensional hole gas Fabricated by Epitaxial Lift-off Method,” Proceedings of the 80th Autumn Meeting of the Japan Society of Applied Physics, 21a-E301-5, 12-395, 2019.
NPL 3: Jin-Kuo Ho et al., “Low-resistance ohmic contacts to p-type GaN”, Applied Physics Letters, vol. 74, no. 9, pp. 1275-1277, 1999.
NPL 4: D. Qiao et al., “A study of the AuONi ohmic contact on p-GaN”, Journal of Applied Physics, vol. 88, no. 7, pp. 4196-4200, 2000.
NPL 5: Jin-Kuo Ho et al., “Low-resistance ohmic contacts to p-type GaN achieved by the oxidation of Ni/Au films”, Journal of Applied Physics, vol. 86, no. 8, pp. 4491-4497, 1999.

### SUMMARY OF THE INVENTION

### Technical Problem

As described above, GaN devices need p-type GaN, but it is difficult to increase hole concentration of GaN. This makes it difficult to form electrodes on p-type GaN with low contact resistance, and application as a device is limited. In addition, in the technique of forming two-dimensional hole gas with an N-polar plane as a main surface orientation to increase hole concentration, the high resistance of the AlGaN layer, which serves as a barrier, makes it difficult to achieve low contact resistance.

The present disclosure has been made to solve the above issues, and an object of the present disclosure is to reduce contact resistance to a two-dimensional hole gas formed in the vicinity of the heterojunction interface between GaN and AlGaN.

### Means for Solving the Problem

A semiconductor device according to the present disclosure includes: a first semiconductor layer including p-type GaN formed on a substrate, the first semiconductor layer having an N polar surface; a second semiconductor layer including undoped AlGaN formed on the first semiconductor layer, the second semiconductor layer having an N polar surface; an electrode including an electrode material containing Ni formed on the second semiconductor layer; and an oxide layer including an oxide of the electrode material, the oxide layer formed between the second semiconductor layer and the electrode so as to be in contact with both the second semiconductor layer and the electrode.

A method for manufacturing a semiconductor device according to the present disclosure, the method including: a first step of forming a first semiconductor layer including p-type GaN on a substrate, the first semiconductor layer having an N polar surface; a second step of forming a second semiconductor layer including undoped AlGaN on the first semiconductor layer, the second semiconductor layer having an N polar surface; a third step of oxidizing a surface of the second semiconductor layer to form a surface oxidized layer including AlGaON; a fourth step of forming an electrode including an electrode material containing Ni on the surface oxidized layer, the electrode being in contact with the surface oxidized layer; and a fifth step of forming an oxide layer including an oxide of the electrode material by heating in a portion of the electrode in contact with the surface oxidized layer, the oxide layer being placed between the electrode and the second semiconductor layer and in contact with both the second semiconductor layer and the electrode.

The semiconductor device according to the present disclosure includes: a collector layer including GaN and formed on a substrate, the collector layer having an N polar surface; a base layer including p-type GaN and formed on the collector layer, the base layer having an N polar surface; an emitter layer including undoped AlGaN, the emitter layer formed on the base layer and having an N polar surface; an emitter electrode formed on the emitter layer; a base electrode including an electrode material containing Ni and formed on the emitter layer placed around the emitter electrode; an oxide layer including an oxide of the electrode material, the oxide layer formed between the emitter layer and the base electrode and being in contact with both the emitter layer and the base electrode; and a collector electrode electrically connected to the collector layer.

A method for manufacturing a semiconductor device according to the present disclosure, the method including: a first step of forming a collector layer including GaN on a substrate, the collector layer having an N polar surface; a second step of forming a base layer including p-type GaN on the collector layer, the base layer having an N polar surface; a third step of forming an emitter layer including undoped AlGaN on the base layer, the emitter layer having an N polar surface; a fourth step of forming an emitter electrode on the emitter layer; a fifth step of oxidizing a surface of the emitter layer positioned around the emitter electrode to form a surface oxidized layer including AlGaON; a sixth step of forming a base electrode including an electrode material containing Ni on the surface oxidized layer, the base electrode being in contact with the surface oxidized layer; a seventh step of forming an oxide layer including an oxide of the electrode material by heating in a portion of the base electrode in contact with the surface oxidized layer, the oxide layer formed between the base electrode and the emitter layer and being in contact with both the emitter layer and the base electrode; and an eighth step of forming a collector electrode electrically connected to the collector layer.

### Effects of the Invention

As described above, according to the present disclosure, an oxide layer including an oxide of an electrode material is formed between a second semiconductor layer (emitter layer) including AlGaN and an electrode (base electrode) so as to be in contact with both the second semiconductor layer (emitter layer) and the electrode (base layer), and consequently the contact resistance to the two-dimensional hole gas formed in the vicinity of the heterojunction interface between GaN and AlGaN can be lowered.

### BRIEF DESCRIPTION OF DRAWINGS

FIG. 1A is a cross-sectional view illustrating a semiconductor device in an intermediate step for describing the method for manufacturing a semiconductor device according to a first embodiment of the present disclosure.

FIG. 1B is a cross-sectional view illustrating the semiconductor device in an intermediate step for describing the method for manufacturing the semiconductor device according to the first embodiment of the present disclosure.

FIG. 1C is a cross-sectional view illustrating the semiconductor device in an intermediate step for describing the method for manufacturing the semiconductor device according to the first embodiment of the present disclosure.

FIG. 1D is a cross-sectional view illustrating the semiconductor device in an intermediate step for describing the method for manufacturing the semiconductor device according to the first embodiment of the present disclosure.

FIG. 2 is a cross-sectional view illustrating another semiconductor device according to the first embodiment of the present disclosure.

FIG. 3A is a cross-sectional view illustrating the semiconductor device in an intermediate step for describing the method for manufacturing the semiconductor device according to the first embodiment of the present disclosure.

FIG. 3B is a cross-sectional view illustrating the semiconductor device in an intermediate step for describing the method for manufacturing the semiconductor device according to the first embodiment of the present disclosure.

FIG. 3C is a cross-sectional view illustrating the semiconductor device in an intermediate step for describing the method for manufacturing the semiconductor device according to the first embodiment of the present disclosure.

FIG. 3D is a cross-sectional view illustrating the semiconductor device in an intermediate step for describing the method for manufacturing the semiconductor device according to the first embodiment of the present disclosure.

FIG. 3E is a cross-sectional view illustrating the semiconductor device in an intermediate step for describing the method for manufacturing the semiconductor device according to the first embodiment of the present disclosure.

FIG. 3F is a cross-sectional view illustrating the semiconductor device in an intermediate step for describing the method for manufacturing the semiconductor device according to the first embodiment of the present disclosure.

FIG. 3G is a cross-sectional view illustrating the semiconductor device in an intermediate step for describing the method for manufacturing the semiconductor device according to the first embodiment of the present disclosure.

FIG. 3H is a cross-sectional view illustrating the semiconductor device in an intermediate step for describing the method for manufacturing the semiconductor device according to the first embodiment of the present disclosure.

FIG. 4A is a cross-sectional view illustrating the semiconductor device in an intermediate step for describing the method for manufacturing the semiconductor device according to the first embodiment of the present disclosure.

FIG. 4B is a cross-sectional view illustrating the semiconductor device in an intermediate step for describing the method for manufacturing the semiconductor device according to the first embodiment of the present disclosure.

FIG. 4C is a cross-sectional view illustrating the semiconductor device in an intermediate step for describing the method for manufacturing the semiconductor device according to the first embodiment of the present disclosure.

FIG. 4D is a cross-sectional view illustrating the semiconductor device in an intermediate step for describing the method for manufacturing the semiconductor device according to the first embodiment of the present disclosure.

### DESCRIPTION OF EMBODIMENTS

Hereinafter, a semiconductor device according to an embodiment of the present disclosure will be described.

### First Embodiment

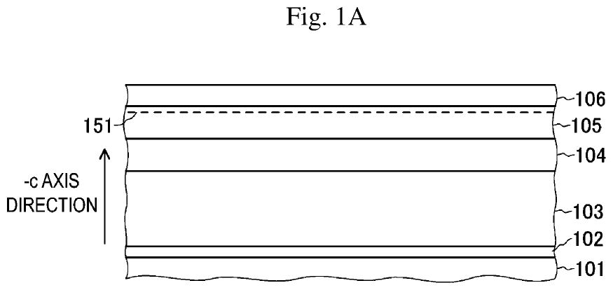

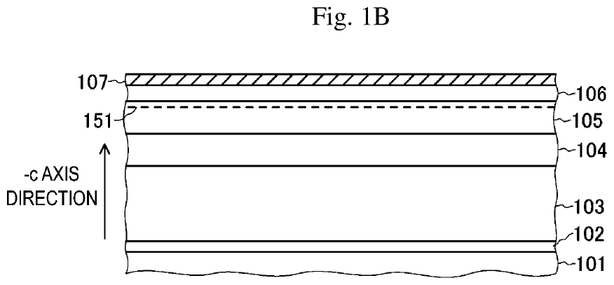

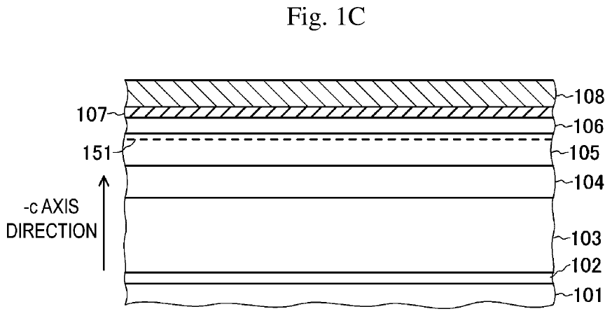

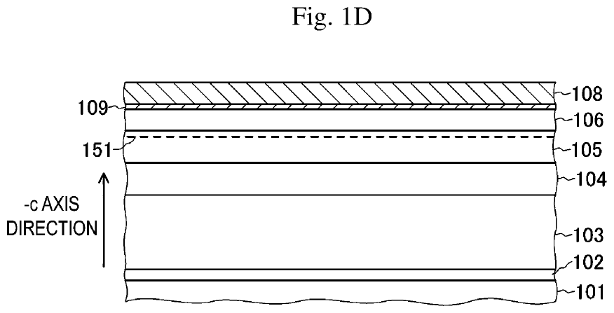

First, a method for manufacturing a semiconductor device according to a first embodiment of the present disclosure will be described with reference to FIGS. 1A to 1D.

First, as illustrated in FIG. 1A, a nucleation layer 102, a buffer layer 103, a p-GaN layer 104, an i-GaN layer 105, and an i-AlGaN layer 106 are epitaxially grown on a substrate 101 in this order (in the −c-axis direction), the layers having an N polar surface (first and second steps).

For example, the first substrate 101 includes Al₂O₃ (sapphire), with the plane orientation of the main surface as (0001). The substrate 101 may include a material that enables crystal growth of nitride semiconductors such as GaN, AlGaN, and InGaN, and whose main surface orientation is an N-polar plane.

The nucleation layer 102 includes, for example, GaN. As is well known, the nucleation layer 102 is a layer to support nucleation in the initial stage of growth to obtain high-quality and flat crystals for crystal growth of nitride semiconductors such as GaN on dissimilar substrates such as Al₂O₃. The nucleation layer 102 has various names, such as “low-temperature buffer layer” or “low-temperature buffer”. By adjusting the nucleation layer 102, the surface of the nucleation layer 102 is made a Group V polar (N polar) plane. By making the surface of the nucleation layer 102 a Group V polar plane, a nitride semiconductor crystal grows on the nucleation layer 102 in the −c axis direction. The nucleation layer 102 is not limited to GaN, and may include other nitride such as MN or AlON. However, when the substrate 101 includes GaN, the nucleation layer 102 may be eliminated.

The buffer layer 103 includes GaN, the p-GaN layer 104 includes p-type GaN, the i-GaN layer 105 includes undoped GaN, and the i-AlGaN layer 106 includes undoped AlGaN. Each of these semiconductor layers can be formed by the well-known metal organic vapor deposition method. These semiconductor layers described above may also be formed (epitaxially grown) by, for example, molecular beam epitaxy (classified as gas source, RF plasma source, laser, etc., but any of these may be used), or hydride vapor phase growth methods.

For example, each semiconductor layer is crystal grown on a growth substrate with group III polarity (Ga polarity) in advance, as described in NPL 2. On the growth substrate, the i-AlGaN layer 106, i-GaN layer 105, and p-GaN layer 104 are laminated in this order from the growth substrate side. This laminate may be attached to other substrate by wafer bonding, and then the growth substrate may be removed to form the semiconductor layer. When the growth substrate is removed after bonding the laminate to other substrate, each layer is laminated on the other substrate (in the −c axis direction), in a state in which the layer has an N polar surface. The p-GaN layer 104, i-GaN layer 105, and i-AlGaN layer 106 are laminated on the other substrate in this order.

For transferring to the other substrate using the growth substrate as described above, a buffer layer is selected differently for growing the i-AlGaN layer 106, i-GaN layer 105, and p-GaN layer 104 on the growth substrate, and the buffer layer is appropriately selected such that the main surface orientation of the buffer layer is a group III polar plane.

In the present embodiment, the plane orientation for the crystal growth is not important, but it is important that the p-GaN layer 104, i-GaN layer 105, and i-AlGaN layer 106 are laminated in this order and the layers have an N polar surface. With this laminated structure, two-dimensional hole gas 151 is generated in the vicinity of the heterojunction interface of the i-AlGaN layer 106, and a high hole concentration can be obtained.

Next, the surface of the i-AlGaN layer 106 is oxidized to form a surface oxidized layer 107 including AlGaON, as illustrated in FIG. 1B (third step). For example, the surface of the i-AlGaN layer 106 can be oxidized by being treated by oxygen plasma. In addition, the surface of the i-AlGaN layer 106 can be oxidized by heating in an atmosphere of air or oxygen. Since AlGaN contains Al, it is more easily oxidized than GaN.

Next, as illustrated in FIG. 1C, an electrode 108 including an electrode material containing Ni is formed in contact with the top of the surface oxidized layer 107 (fourth step). For example, the electrode 108 can be formed by depositing Ni using electron beam deposition or sputtering.

Next, as illustrated in FIG. 1D, an oxide layer 109 including an oxide of the electrode 108 material is formed by heating in a portion of the electrode 108 in contact with the surface oxidized layer 107 (fifth step). The oxide layer 109 is placed between the electrode 108 and the i-AlGaN layer 106 in contact with both the i-AlGaN layer 106 and the electrode 108.

By heating, a portion of the electrode 108 combines with the oxygen included in the surface oxidized layer 107 to form NiO to form the oxide layer 109. NiO is easily converted to p-type and efficiently forms an ohmic contact with the two-dimensional hole gas 151. The temperature and time of the heat treatment are set to an appropriate temperature and time to obtain an ohmic contact between the oxide layer 109 and the two-dimensional hole gas 151.

The above-described manufacturing method provides a semiconductor device including: a p-GaN layer 104 including p-type GaN and formed on a substrate 101 so as to have an N polar surface; an i-AlGaN layer 106 including undoped AlGaN and formed on the p-GaN layer 104 so as to have an N polar surface; an electrode 108 including an electrode 108 material containing Ni and formed on the i-AlGaN layer 106; and an oxide layer 109 including an oxide of the electrode 108 material and formed between the i-AlGaN layer 106 and the electrode 108 in such a manner that the oxide layer is in contact with both the i-AlGaN layer 106 and the electrode 108. The oxide layer 109 is in ohmic contact with a two-dimensional hole gas. The two-dimensional hole gas is formed in the vicinity of the interface with the i-AlGaN layer 106 on the p-GaN layer 104.

According to the first embodiment, since the oxide layer 109 including an oxide of the electrode material that constitutes the electrode 108 is included (formed), the contact resistance to the two-dimensional hole gas 151 formed in the vicinity of the heterojunction interface between GaN and AlGaN can be lowered.

The oxide layer 109 is formed by replacing part of the surface oxidized layer 107 with NiO. The surface oxidized layer 107 is formed of a portion of the i-AlGaN layer 106. For these reasons, the formation of the oxide layer 109 reduces the effective layer thickness of the i-AlGaN layer 106 as a barrier layer. The decrease in the effective layer thickness of the i-AlGaN layer 106 leads to a decrease in the concentration of the two-dimensional hole gas 151 immediately below the i-AlGaN layer 106. In order to reduce this decrease in the concentration of two-dimensional hole gas 151 and to obtain the ohmic contact described above, the conditions for forming the surface oxidized layer 107 need to be properly selected.

As described above, the surface of the substrate has been designed to be an N-polar plane, but the surface is not necessarily an N-polar plane. As described above using FIG. 1A, each semiconductor layer is grown with an N-polar plane as the main surface orientation, and the surface of the i-AlGaN layer 106 is oxidized to form the surface oxidized layer 107 to form the electrode 108.

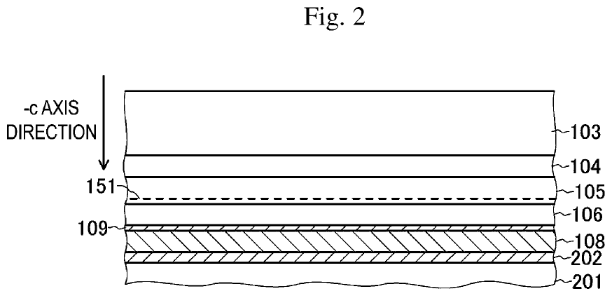

Then, as illustrated in FIG. 2, the electrode 108 of the substrate 101 is bonded onto other substrate 201 via an adhesive metal layer 202 by wafer bonding, and the substrate 101 is removed, so that the semiconductor layers are laminated on the other substrate 201 to have a group III surface. A proper material is selected for the adhesive metal layer 202 in terms of wafer bonding. For example, the adhesive metal layer 202 may include Au. The surface of the adhesive metal layer 202 may lose its surface flatness due to the heat treatment process to form the oxide layer 109. In this case, the adhesive metal layer 202 is planarized by techniques such as chemical mechanical polishing.

As described above, the electrode 108 includes Ni, but other substance in addition to Ni can be included to improve adhesiveness with the semiconductor layer. In this case, the electrode 108 may be formed with a laminated structure in which Ti is deposited after Ni, or Ni is deposited after Ti, to the extent that the effects of the present disclosure is not inhibited.

### Second Embodiment

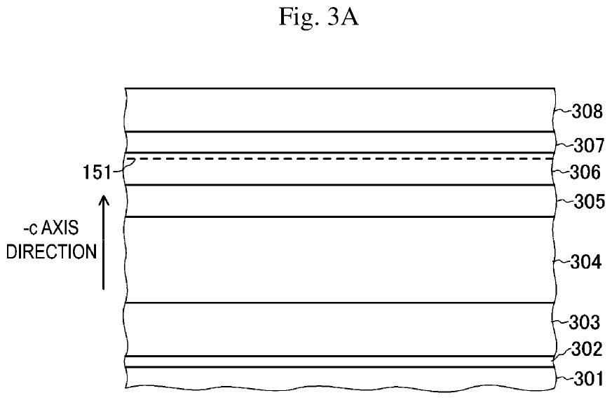

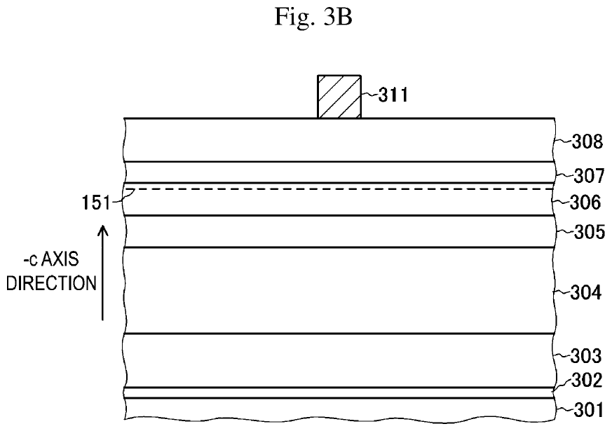

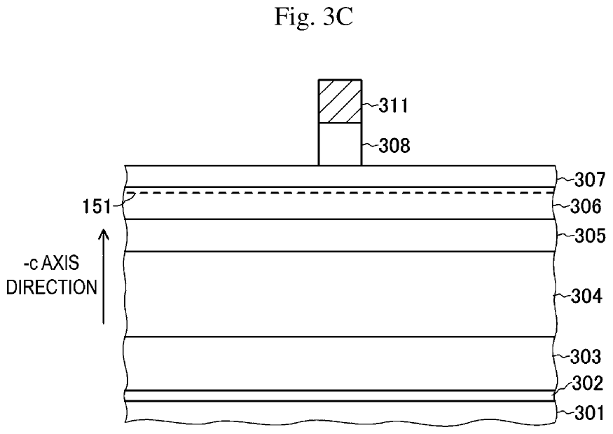

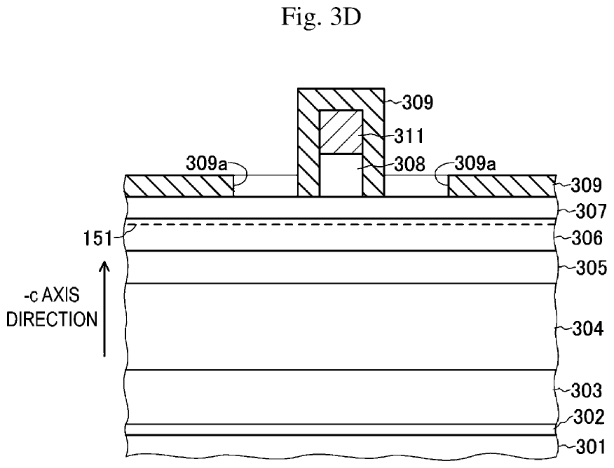

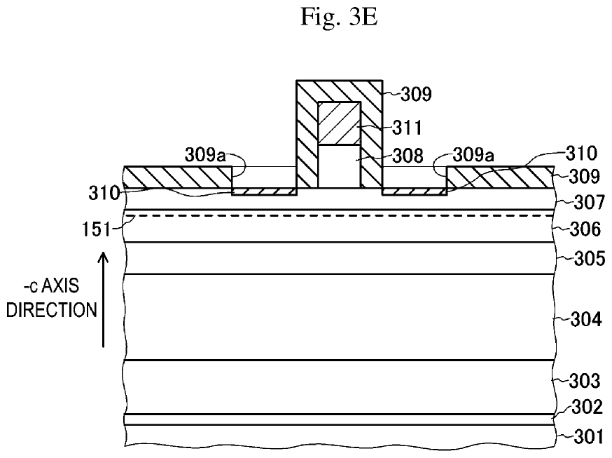

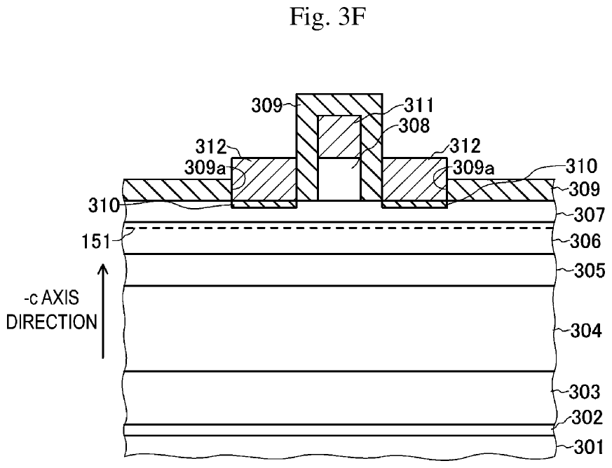

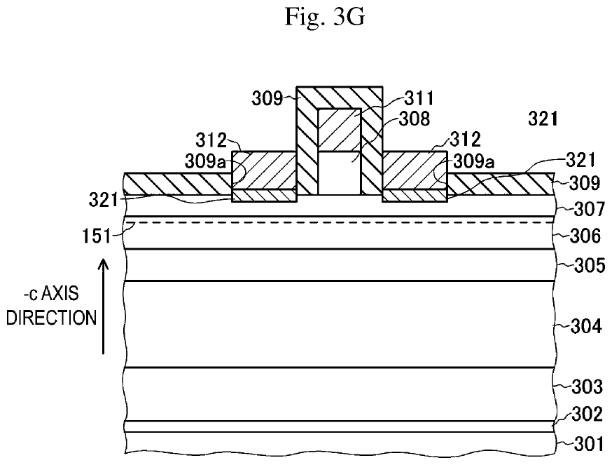

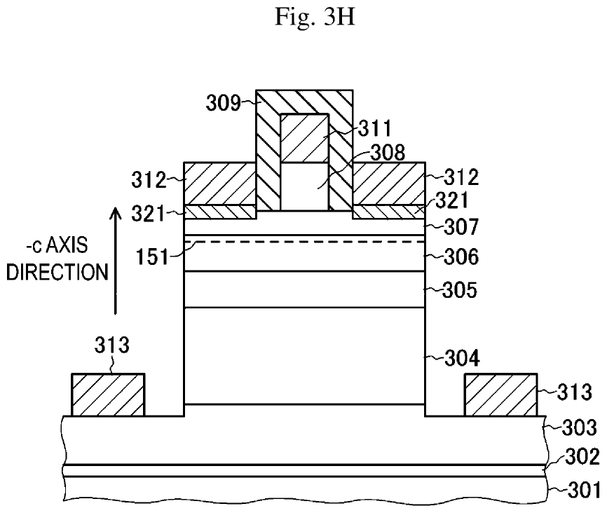

Next, a manufacturing method of a semiconductor device according to a second embodiment of the present disclosure will be described with reference to FIGS. 3A to 3H. Hereinafter, a heterojunction bipolar transistor will be described as an example of the semiconductor device.

First, as illustrated in FIG. 3A, a nucleation layer 302, a sub-collector layer 303, a collector layer 304, a p-base layer 305, an i-base layer 306, an emitter layer 307, and an emitter cap layer 308 are epitaxially grown in this order on a substrate 301 (in the −c-axis direction), in a state in which the layers have an N polar surface (first, second, and third steps).

For example, the substrate 301 includes Al₂O₃ (sapphire), with the plane orientation of the main surface as (0001). The substrate 301 may include a material that enables crystal growth of nitride semiconductors such as GaN, AlGaN, and InGaN, and whose main surface orientation is an N-polar plane.

The nucleation layer 302 includes, for example, GaN. As is well known, the nucleation layer 302 is a layer to support nucleation in the initial stage of growth to obtain high-quality and flat crystals for crystal growth of nitride semiconductors such as GaN on dissimilar substrates such as Al₂O₃. The nucleation layer 302 has various names, such as “low-temperature buffer layer” or “low-temperature buffer”. By adjusting the nucleation layer 302, the surface of the nucleation layer 302 is made a Group V polar (N polar) plane. By making the surface of the nucleation layer 302 a Group V polar plane, the nitride semiconductor crystal grows on the nucleation layer 302 in the −c axis direction. The nucleation layer 302 is not limited to GaN, and may include other nitride such as MN or AlON. However, when the substrate 301 includes GaN, the nucleation layer 302 may be eliminated.

The sub-collector layer 303 includes n-type GaN. The sub-collector layer 303 may be doped to an n-type at a high concentration to form an ohmic contact with the collector electrode described later. The sub-collector layer 303 can also reduce the dislocation density as the layer thickness increases, and has the effect of improving crystal quality. Accordingly, the sub-collector layer 303 can be formed to have a thickness of about several micrometers, which is relatively thick.

The collector layer 304 includes undoped GaN. The collector layer 304 may include n-type GaN. The collector layer 304 is a layer that determines the withstand voltage of the heterojunction bipolar transistor, and determines the thickness and the doping concentration according to the specifications.

The p-base layer 305 includes p-type GaN with Mg as dopants, for example. The p-base layer 305 preferably is a p-type having a concentration as high as possible, to form an ohmic contact with the base electrode as described later.

The i-base layer 306 includes undoped GaN, and the emitter layer 307 includes undoped AlGaN. With this configuration, the interface between the i-base layer 306 and the emitter layer 307 has a band bent by the spontaneous and piezoelectric polarization electric fields, and has a valence band edge above the Fermi level. As a result, a two-dimensional hole gas 151 is formed in the vicinity of the interface on the side of the i-base layer 306. The emitter cap layer 308 includes n-type AlGaN in which n-type impurities are included at high concentration. Each of these semiconductor layers can be formed by the well-known metal organic vapor deposition method. These semiconductor layers described above may also be formed (epitaxially grown) by, for example, molecular beam epitaxy (classified as gas source, RF plasma source, laser, etc., but any of these may be used), or hydride vapor phase growth methods.

Next, as illustrated in FIG. 3B, an emitter electrode 311 is formed on the emitter layer 307 (fourth step). In this example, an emitter electrode 311 is formed on the emitter layer 307 via the emitter cap layer 308. For example, the emitter electrode 311 can be formed by depositing an electrode material on the emitter cap layer 308 using a known deposition technique such as sputtering or vapor deposition to form a metal layer, and patterning this metal layer using known lithography and etching techniques.

For the emitter electrode 311, an electrode material that can form an ohmic contact with n-GaN included in the emitter cap layer 308 is appropriately selected. The electrode material may include a single material, and, for example, may be formed by a laminated structure of a material such as Ni, Ti, Al, or Au that can form an ohmic contact with n-GaN. In addition, annealing or other treatment may be performed to form an ohmic contact between the emitter electrode 311 and the emitter cap layer 308. This annealing treatment may damage the flatness of an electrode surface and the surface of an epitaxial wafer, and thus an appropriate protective film is deposited before performing the annealing treatment.

Next, as illustrated in FIG. 3C, the emitter cap layer 308 is patterned into a mesa shape. For example, by using the emitter electrode 311 as a mask and selectively etching the emitter cap layer 308 using known etching technique, the emitter cap layer 308 can be processed into a predetermined mesa shape (first mesa).

Next, as illustrated in FIG. 3D, a protective film 309 having an opening 309a is formed in a base electrode formation region. Next, as illustrated in FIG. 3E, the surface of the emitter layer 307 around the emitter electrode 311 and exposed to the opening 309a is oxidized to form a surface oxidized layer 310 including AlGaON (fifth step). For example, the surface oxidized layer 310 can be formed by oxygen plasma irradiation technique or annealing treatment in air or oxygen atmosphere. Since AlGaN is more easily oxidized than GaN due to the presence of Al, the surface oxidized layer 310 can be formed by the oxidation treatment described above.

Next, as illustrated in FIG. 3F, a base electrode 312 including an electrode material containing Ni is formed in contact with the top of the surface oxidized layer 310 (sixth step). For example, the base electrode 312 can be formed by depositing Ni using electron beam deposition or sputtering.

After forming the base electrode 312 on the surface oxidized layer 310 as described above, this element is subjected to heat treatment. This heat treatment forms an oxide layer including an oxide of the electrode material (NiO) in the portion of the base electrode 312 in contact with the surface oxidized layer 310, and as illustrated in FIG. 3G, an oxide layer 321 is placed between the base electrode 312 and the emitter layer 307 in contact with both the emitter layer 307 and the base electrode 312 (seventh step).

This heating causes a portion of the base electrode 312 to combine with oxygen constituting the surface oxidized layer 310 to form NiO, to form the oxide layer 321. NiO is easily converted to p-type and efficiently forms an ohmic contact with the two-dimensional hole gas 151. The temperature and time of the heat treatment are set to an appropriate temperature and time to obtain an ohmic contact between the oxide layer 321 and the two-dimensional hole gas 151.

Next, by patterning the emitter layer 307, i-base layer 306, p-base layer 305, collector layer 304, and a portion of the sub-collector layer 303 in the thickness direction, these layers are made into a mesa shape, as illustrated in FIG. 3H. This mesa shape (second mesa) is, for example, a rectangle in plan view. The second mesa described above has a larger area in plan view than the first mesa of the emitter cap layer 308.

After forming the second mesa as described above, a collector electrode 313 is formed on the sub-collector layer 303 around the second mesa. The collector electrode 313 is electrically connected to the collector layer 304 through the sub-collector layer 303 (eighth step).

The manufacturing method described above provides a heterojunction bipolar transistor (semiconductor device) including: a collector layer 304 including GaN and formed on a substrate 301, the collector layer 304 having an N polar surface; a p-base layer 305 including p-type GaN and formed on the collector layer 304, the p-base layer 305 having an N polar surface; an emitter layer 307 including undoped AlGaN formed on the p-base layer 305, the emitter layer 307 having an N polar surface; an emitter electrode 311 formed on the emitter layer 307; a base electrode 312 including an electrode material containing Ni and formed on the emitter layer 307 around the emitter electrode 311; an oxide layer 321 including an oxide of an electrode material and formed between the emitter layer 307 and the base electrode 312 so as to be in contact with both the emitter layer 307 and the base electrode 312; and a collector electrode 313 electrically connected to the collector layer 304. The oxide layer 321 is in ohmic contact with the two-dimensional hole gas formed in the vicinity of the interface of the p-base layer 305 with the emitter layer 307.

According to the second embodiment, since the oxide layer 321 including an oxide of the electrode material that constitutes the base electrode 312 is included (formed), the contact resistance to the two-dimensional hole gas 151 formed in the vicinity of the heterojunction interface between GaN and AlGaN can be lowered.

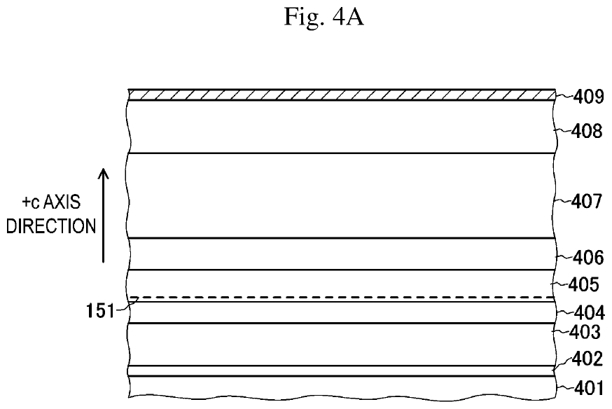

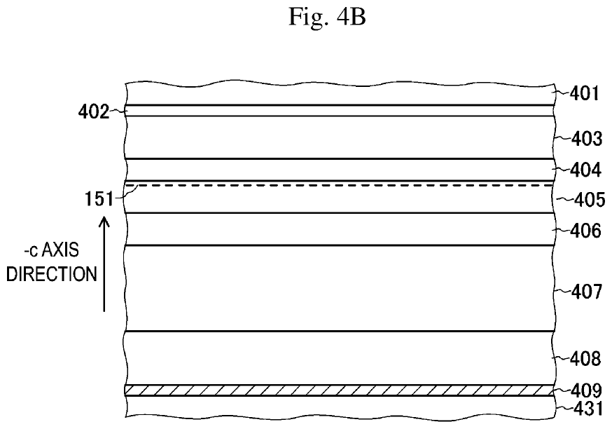

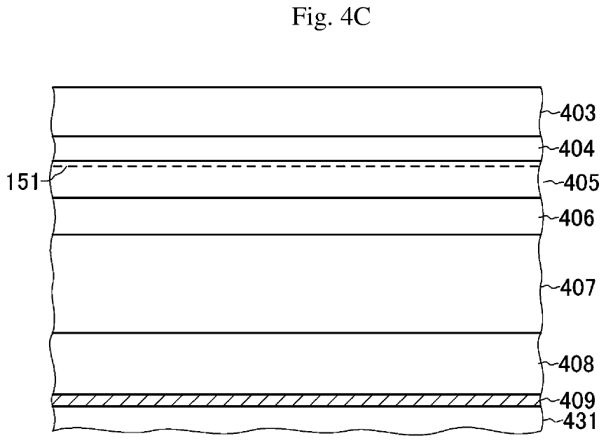

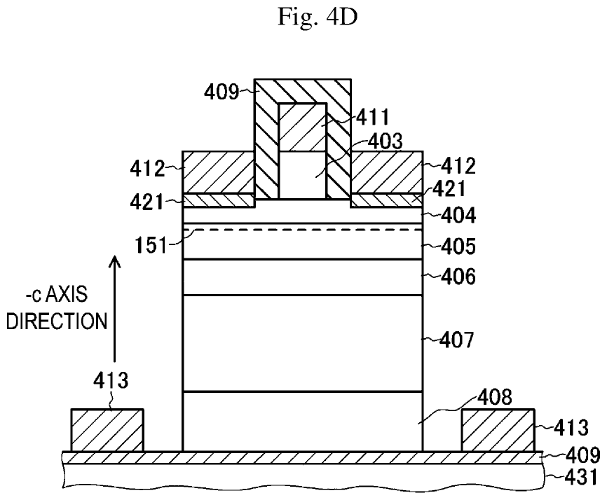

As described above, the surface of the substrate has been designed to be an N-polar plane, but the surface is not necessarily an N-polar plane. For example, as illustrated in FIG. 4A, a nucleation layer 402, an emitter cap layer 403, an emitter layer 404, an i-base layer 405, a p-base layer 406, a collector layer 407, and a sub-collector layer 408 are epitaxially grown in this order (in the +c-axis direction) on a growth substrate 401 in a state in which the layers have a group III polar plane.

For example, the growth substrate 401 includes Al₂O₃ (sapphire), with the plane orientation of the main surface as (0001). The growth substrate 401 may include a material that enables crystal growth of nitride semiconductors such as GaN, AlGaN, and InGaN, and whose main surface orientation is an N-polar plane.

The nucleation layer 402 includes, for example, GaN. The emitter cap layer 403 includes n-type AlGaN in which n-type impurities are included at high concentration. The emitter layer 404 includes undoped AlGaN, and the i-base layer 405 includes undoped GaN. With this configuration, the interface between the i-base layer 405 and the emitter layer 404 has a band is bent by the spontaneous and piezoelectric polarization electric fields, and has a valence band edge above the Fermi level. As a result, the two-dimensional hole gas 151 is formed in the vicinity of the interface on the side of the i-base layer 405.

The p-base layer 406 includes p-type GaN. The collector layer 407 includes undoped GaN. The sub-collector layer 408 includes n-type GaN. Each of these semiconductor layers can be formed by the well-known metal organic vapor deposition method. These semiconductor layers described above may also be formed (epitaxially grown) by, for example, molecular beam epitaxy (classified as gas source, RF plasma source, laser, etc., but any of these may be used), or hydride vapor phase growth methods. In addition, a metal layer 409 made of a metal is formed on the sub-collector layer 408.

Next, as illustrated in FIG. 4B, the metal layer 409 is used as an adhesive layer, and a heat dissipation substrate 431, which has high heat dissipation, is attached to the metal layer 409 by wafer bonding. Before bonding, the surface of the metal layer 409 may be planarized by techniques such as chemical mechanical polishing. In this configuration, when viewed from the side of the heat dissipation substrate 431, the semiconductor layers are laminated (in the −c axis direction) so as to have an N polar surface.

Next, the nucleation layer 402 and the growth substrate 401 are removed to expose the surface of the emitter cap layer 403, as illustrated in FIG. 4C. Thereafter, by following the same steps as described using FIGS. 3B to 3H, an emitter electrode 411 is formed on the emitter layer 404 and the emitter cap layer 403 is patterned into a mesa shape, as illustrated in FIG. 4D.

In addition, a base electrode 412 is formed on the emitter layer 404 via an oxide layer 421, and then the emitter layer 404, i-base layer 405, p-base layer 406, collector layer 407, and sub-collector layer 408 are patterned to make these layers into a mesa shape. After the mesa is formed as described above, a collector electrode 413 is formed on the metal layer 409 around the mesa. The collector electrode 413 is electrically connected to the collector layer 407 through the metal layer 409 and sub-collector layer 408. In this configuration, the metal layer 409 may be used as a collector electrode and a collector contact may be formed on the back side of the heat dissipation substrate 431.

As described above, according to the present disclosure, an oxide layer including an oxide of an electrode material is formed between a second semiconductor layer (emitter layer) including AlGaN and an electrode (base electrode) so as to be in contact with both the second semiconductor layer (emitter layer) and the electrode (base layer), and consequently the contact resistance to the two-dimensional hole gas formed in the vicinity of the heterojunction interface between GaN and AlGaN can be lowered.

Meanwhile, the present disclosure is not limited to the embodiments described above, and it is obvious to those skilled in the art that various modifications and combinations be implemented within the technical idea of the present disclosure.

### REFERENCE SIGNS LIST

101 Substrate
102 Nucleation layer
103 Buffer layer
104 p-GaN layer
105 i-GaN layer
106 i-AlGaN layer
107 Surface oxidized layer
108 Electrode
109 Oxide layer
151 Two-dimensional hole gas

1. A method for manufacturing a semiconductor device, the method comprising:
a first step of forming a p-GaN layer including p-type GaN on a substrate, the p-GaN layer having an N polar surface;
a second step of forming an AlGaN layer including undoped AlGaN on the p-GaN layer, the AlGaN layer having an N polar surface;
a third step of oxidizing a surface of the AlGaN layer to form a surface oxidized layer including AlGaON;
a fourth step of forming an electrode including an electrode material containing Ni on the surface oxidized layer, the electrode being in contact with the surface oxidized layer; and
a fifth step of forming an oxide layer including an oxide of the electrode material by heating in a portion of the electrode in contact with the surface oxidized layer, the oxide layer formed between the electrode and the AlGaN layer and in contact with both the AlGaN layer and the electrode.

2. The method for manufacturing a semiconductor device according to claim 1, wherein
the oxide layer is in ohmic contact with a two-dimensional hole gas formed in the vicinity of an interface of the p-GaN layer with the AlGaN layer.

3. A semiconductor device comprising:
a p-GaN layer including p-type GaN and formed on a substrate, the p-GaN layer having an N polar surface;
an AlGaN layer including undoped AlGaN and formed on the p-GaN layer, the AlGaN layer having an N polar surface;
an electrode including an electrode material containing Ni and formed on the AlGaN layer; and
an oxide layer including an oxide of the electrode material, the oxide layer formed between the AlGaN layer and the electrode and being in contact with both the AlGaN layer and the electrode.

4. The semiconductor device according to claim 3, wherein
the oxide layer is in ohmic contact with a two-dimensional hole gas formed in the vicinity of an interface of the p-GaN layer with the AlGaN layer.

5. A method for manufacturing a semiconductor device, the method comprising:
a first step of forming a collector layer including GaN on a substrate, the collector layer having an N polar surface;
a second step of forming a base layer including p-type GaN on the collector layer, the base layer having an N polar surface;
a third step of forming an emitter layer including undoped AlGaN on the base layer, the emitter layer having an N polar surface;
a fourth step of forming an emitter electrode on the emitter layer;
a fifth step of oxidizing a surface of the emitter layer positioned around the emitter electrode to form a surface oxidized layer including AlGaON;
a sixth step of forming a base electrode including an electrode material containing Ni on the surface oxidized layer, the base electrode being in contact with the surface oxidized layer;
a seventh step of forming an oxide layer including an oxide of the electrode material by heating in a portion of the base electrode in contact with the surface oxidized layer, the oxide layer formed between between the base electrode and the emitter layer and being in contact with both the emitter layer and the base electrode; and
an eighth step of forming a collector electrode electrically connected to the collector layer.

6. The method for manufacturing a semiconductor device according to claim 5, wherein
the oxide layer is in ohmic contact with a two-dimensional hole gas formed in the vicinity of an interface of the base layer with the emitter layer.

7. A semiconductor device comprising:
a collector layer including GaN and formed on a substrate, the collector layer having an N polar surface;
a base layer including p-type GaN formed on the collector layer, the base layer having an N polar surface;
an emitter layer including undoped AlGaN formed on the base layer, the emitter layer having an N polar surface;
an emitter electrode formed on the emitter layer;
a base electrode including an electrode material containing Ni and formed on the emitter layer around the emitter electrode;
an oxide layer including an oxide of the electrode material, the oxide layer formed between the emitter layer and the base electrode and being in contact with both the emitter layer and the base electrode; and
a collector electrode electrically connected to the collector layer.

8. The semiconductor device according to claim 7,
wherein the oxide layer is in ohmic contact with a two-dimensional hole gas formed in the vicinity of an interface of the base layer with the emitter layer.
